(19) United States
(12) Patent Application Publication
(10) Pub. No.: US 2010/0022101 A1
(43) Pub. Date: Jan. 28, 2010

(54) METHOD FOR CHANGING PHYSICAL VAPOR DEPOSITION FILM FORM

(75) Inventor: YI-HAO TING, YUNLIN COUNTY (TW)

Correspondence Address: ROSENBERG, KLEIN & LEE, 3458 ELLICOTT CENTER DRIVE-SUITE 101, ELLICOTT CITY, MD, 21043, US

(73) Assignee: INOTERA MEMORIES, INC., TAOYUAN COUNTY (TW)

(21) Appl. No.: 12/243,356

(22) Filed: Oct. 1, 2008

(30) Foreign Application Priority Data
Jul. 25, 2008 (TW) 97128285

(51) Int. Cl. H01L 21/31

(52) U.S. Cl. 438/782; 257/E21.24

(57) ABSTRACT

A method for changing a physical vapor deposition film form comprises: providing at least one sample with an active area; delivering the sample to a physical vapor deposition machine with one adjustable angle of one collimator; changing the angle of the collimator in the physical vapor deposition machine; performing physical vapor deposition operation, forming a uniform thin film disposed on one active area of the sample.

### BACKGROUND OF THE INVENTION

1. Field of the Invention

The present invention is related to a method for changing a film form; in particular, to a method for changing a physical vapor deposition film form.

2. Description of Related Art

Conventional thin film depositions, also referred as thin film growth, are normally used to form a dielectric layer, metal layer or polysilicon layer and so forth on a semiconductor substrate. For instance, a dielectric layer, made of a material such as silicon dioxide (SiO₂) or silicon nitride (Si₃N₄), can be used as a mask (also referred as protection layer) for protecting components in a diffusion process or an ion plantation process. The metal layer and polysilicon layer can be used electric connectors as metal wirings between components and gate electrode materials in the Metal-Oxide-Semiconductor (MOS) structure. The process of film deposition further requires masking using photolithography technology.

Physical Vapor Deposition (PVD) is one type of conventional film depositions employed in semiconductor processes, which uses non-chemical physical phenomena to perform film deposition. PVD comprises conventional evaporation and deposition and more advanced sputtering. Evaporation performs film deposition by heating the evaporation material in a vacuum and using the saturated vapor pressure present when the evaporation material is close to its melting point; sputtering employs plasma ions generated from plasma to bombard the sputtering materials, allowing the plasma ions to be in vapor state to carry the sputtering material atoms thus completing the desired film deposition. However, both approaches sometimes produce metal and non-metal films with uneven thickness.

Refer now to FIGS. 1A to 1C, wherein a substrate 100 is provided and has a Gate Conductor (GC) structure 102; a plurality of Phosphoborosilicate Glass (PBSG) layers 104 is formed, in which the PBSG layer 104 partially covers the GC structure 102; After using self-aligned process with lithography and dry etch processes, we can have a contact hole between two adjacent GC structures 102 which called CB (Contact to Bitline) layer 108 shown in liner layers 106. Said plurality of liner layers 106 are deposited on the surface and the sidewalls of the BPSG layer 104 and the GC structure 102 and the bottom of the CB layer 108; after completion of the processes described supra, the finished substrate is placed under an TEM (Transmission Electron Microscope) inspection for sampling. Refer now to FIG. 2, wherein a CB (Contact to Bitline) contact 110 landing on a non-flat substrate (also known as the corner of an active area) has said plurality of liner layers 106 deposited on the bottom and the sidewalls; that is, thickness of one end of the CB contact 110 is greater than the other end of the CB contact 110.

Uneven thickness may cause the following problems: being improperly thin in the thickness may result in worm hole or electrical leakage effects; while being overly thick may otherwise generate poor electrical performance or particle defect therein. Both said situations undesirably reduce yield of entire semiconductor processes.

Accordingly, the inventors of the present invention have considered the above-mentioned improvable defects, and, based on long-term professional experiences, together with thorough researches and observations, in conjunction with applications of fundamental theories, thus proposed the present invention having reasonable design and effectiveness in amelioration of the aforementioned disadvantages.

### SUMMARY OF THE INVENTION

Hence, the object of the present invention is to provide a method for changing a physical vapor deposition film form in order to achieve the objective for increasing semiconductor process yield.

According to the above-mentioned objective of the present invention, the present invention proposes a method for changing a physical vapor deposition film form, comprising the following steps: providing at least one sample having an active area; transferring the sample to a Physical Vapor Deposition (PVD) tool, wherein the PVD tool is installed with a collimator having an adjustable angle; changing the angle of the collimator in the PVD tool by means of electrical drive; and performing PVD operations to form a film having uniform thickness, the formed film covering the active area of the sample.

The present invention provides the following beneficial effects: the PVD tool is installed with a collimator having an adjustable angle, facilitating formation of a film with even thickness on the active area of the sample, so as to achieve the objective for increasing semiconductor process yield.

### BRIEF DESCRIPTION OF THE DRAWINGS

FIGS. 1A to 1C are plan view diagrams of the conventional film deposition.

FIG. 2 is a high-resolution TEM (Transmission Electron Microscope) diagram of the conventional film deposition.

FIG. 3 is a flowchart of the method for changing a physical vapor deposition film form according to the present invention.

FIG. 4A is a top view diagram of the collimator according to the present invention.

FIG. 4B is a cross-section view diagram of the collimator according to the present invention.

FIG. 5 is a plan view diagram of the method for changing a physical vapor deposition film form according to the present invention.

FIG. 6 is a flowchart of another method for changing a physical vapor deposition film form according to the present invention.

FIG. 7 is a flowchart of yet another method for changing a physical vapor deposition film form according to the present invention.

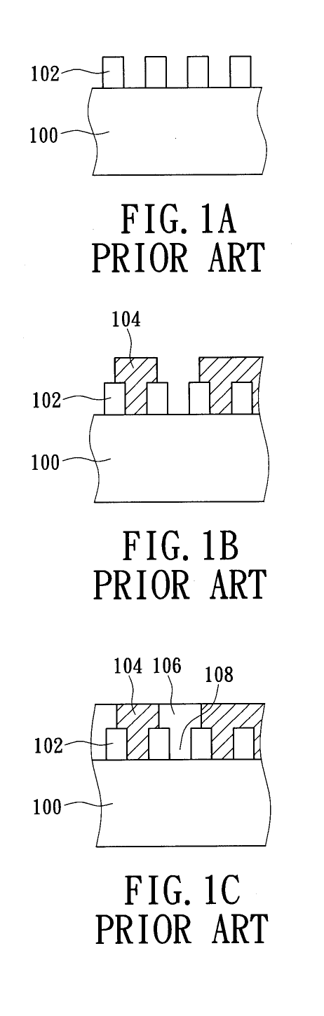

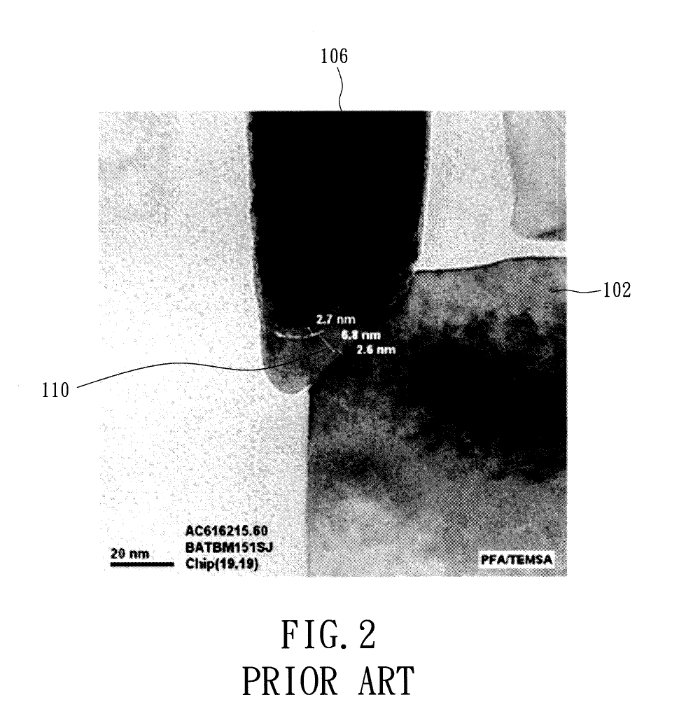

### DETAILED DESCRIPTION OF PREFERRED EMBODIMENTS

### First Embodiment

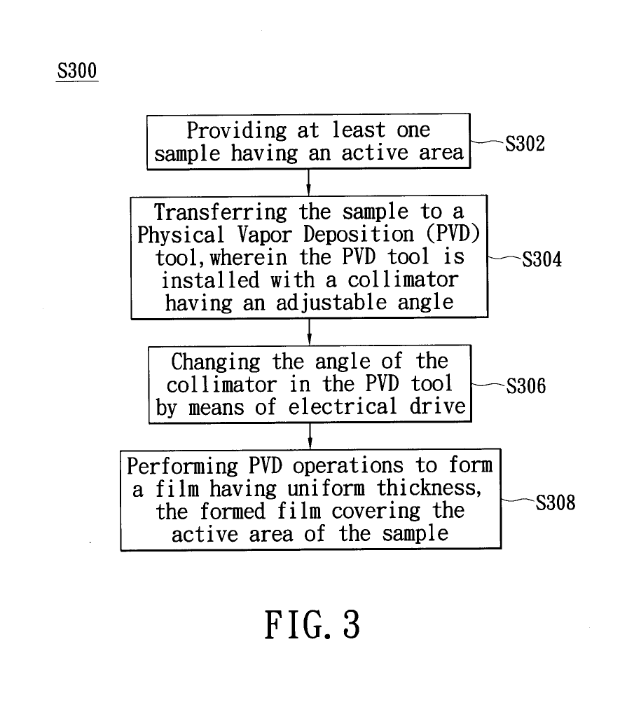

Refer to FIG. 3, wherein a method S300 for changing a physical vapor deposition film form according to the present invention is shown, comprising:

performing step S302, herein providing at least one sample, which has an active area. In the present embodiment, the sample is a semiconductor component and the active area is a contact hole or a via pattern which lands on a non-flat area, wherein the contact hole can be singular or plural, and the via pattern can be singular or plural.

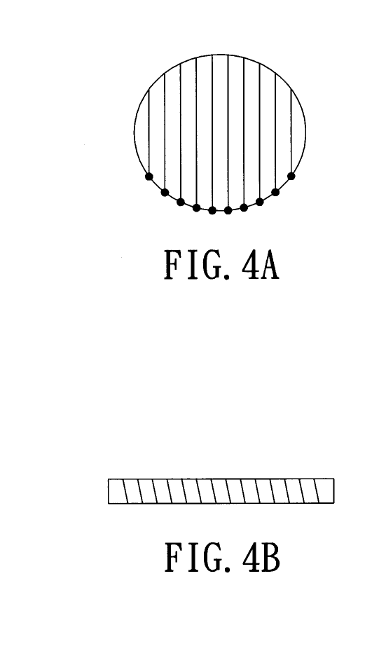

performing step S302, herein transferring the sample to a Physical Vapor Deposition (PVD) tool, which is provided with a collimator having an adjustable angle, and said collimator has a plurality of filter components which can be in a form of stripe or non-stripe; in the present embodiment, by referring to FIGS. 4A and 4B, said plurality of filter components are stripe-shaped.

performing step S306, herein changing the angle of the collimator installed in the PVD tool by means of electrical drive. In the present embodiment, such a range of adjustment for changing the angle of the collimator relative to a vertical plan is between about −20° to 20°.

performing step S308, herein executing PVD operations thus forming a film with uniform thickness, the film covering on an active area of the sample. Said film is composed of a material selected from the group containing the followings: Al, Mo, Nd, AINd, W, Cr, Ta, Ti, Cu, AlₓN_{y}, MoₓN_{y}, TaN, TiN, and other metal nitrides, alloys as well as combinations thereof. In the present embodiment, the film is composed of a group of materials including combinations of titanium, titanium nitride.

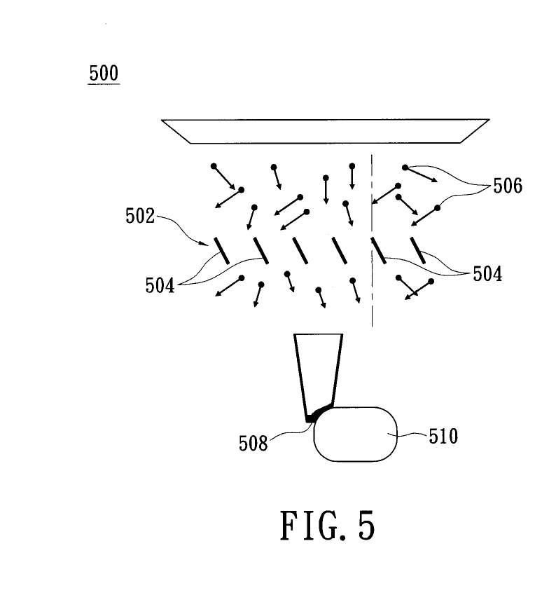

Refer now to FIG. 5, wherein the PVD tool 500 is installed with a collimator 502 having an adjustable angle and having a plurality of filter components 504. A plurality of triggered ions 506 pass through the plurality of filter components 504 thus forming a film 508 with uniform thickness. Said film 508 covers the active area 510 of the sample.

### Second Embodiment

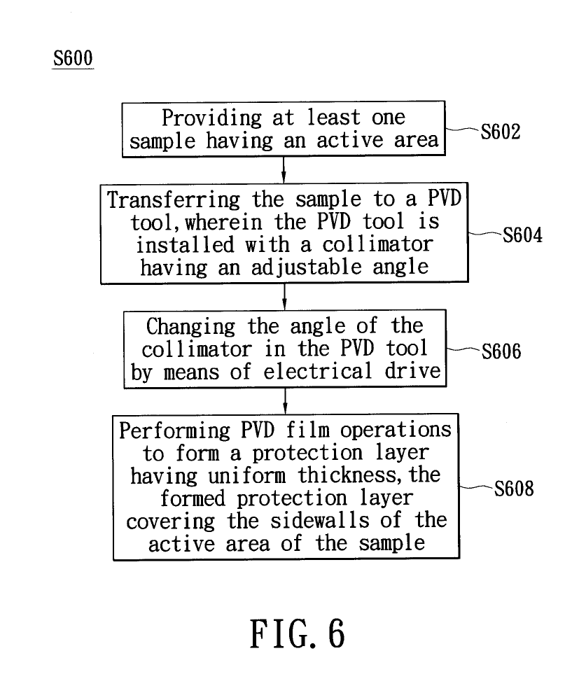

Refer now to FIG. 6, wherein another method S600 for changing a physical vapor deposition film form according to the present invention is shown, comprising the following steps: performing step S602, herein providing at least one sample, which has an active area, wherein the active area is a contact hole or a via pattern or single side of a line pattern needed special protection, and the contact hole, the via pattern, and the line pattern can be singular or plural; performing step S604, transferring the sample to a PVD tool, which is installed with a collimator having an adjustable angle; performing step S606, herein changing the angle of the collimator installed in the PVD tool by means of electrical drive; performing step S608, herein executing PVD operations thus forming a protection layer with a uniform thickness, the protection layer covering the sidewalls of the active area of the sample.

### Third Embodiment

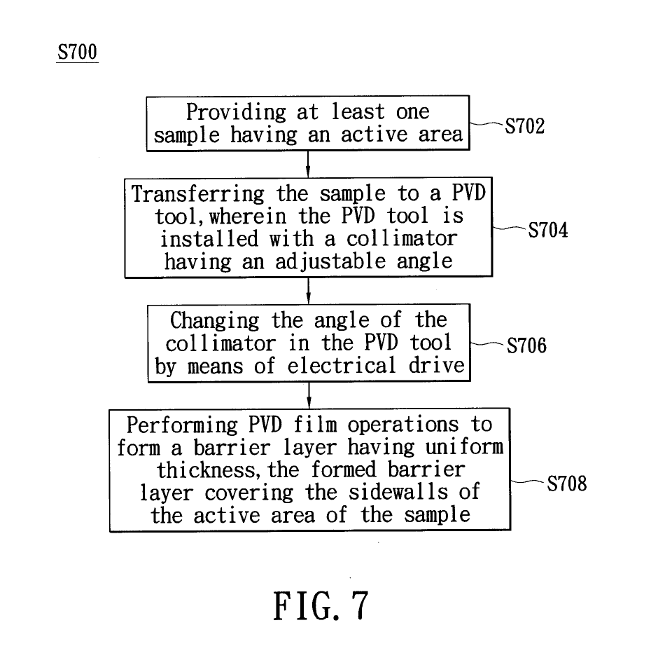

Refer now to FIG. 7, a flowchart of yet another method S700 for changing a physical vapor deposition film form according to the present invention is shown, comprising the following steps: performing step S702, herein providing at least one sample, which has an active area, wherein the active area is a contact hole or a via pattern or a single side of a line pattern needed special barrier layer covering, and the contact hole, the via pattern, and the line pattern can be singular or plural; performing step S704, transferring the sample to a PVD tool, which is installed with a collimator having an adjustable angle; performing step S706, herein changing the angle of the collimator installed in the PVD tool by means of electrical drive; performing step S708, herein executing PVD operations thus forming a barrier layer with a uniform thickness, the barrier layer covering the sidewalls of the active area of the sample.

Compared with the conventional art, the present invention achieves the subsequent effects:

1. the PVD tool 500 installed with the collimator 502 having an adjustable angle facilitates formation of the film 508 having uniform thickness covering the active area 510 of the sample, achieving the objective of for increasing semiconductor process yield.

2. the PVD tool 500 installed with the collimator 502 having an adjustable angle facilitates formation of a protection layer having uniform thickness covering the sidewalls of the active area 510 of the sample, achieving the objective of for increasing semiconductor process yield.

3. the PVD tool 500 installed with the collimator 502 having an adjustable angle facilitates formation of a barrier layer having uniform thickness covering the sidewalls of the active area 510 of the sample, achieving the objective of for increasing semiconductor process yield.

The aforementioned descriptions simply illustrate the preferred embodiments of the present invention, without any intention to restrict the scope of the present invention thereto. All changes and modifications equivalent in effectiveness made based on the specifications and drawings of the present invention are similarly deemed to be encompassed by the scope of legal protection defined in the claims set forth hereunder.

What is claimed is:

1. A method for changing a physical vapor deposition film form, comprising the following steps:
providing at least one sample having an active area;
transferring the sample to a Physical Vapor Deposition (PVD) tool, wherein the PVD tool is installed with a collimator having an adjustable angle;
changing the angle of the collimator in the PVD tool by means of electrical drive; and
performing PVD operations to form a film having uniform thickness, the formed film covering the active area of the sample.

2. The method for changing a physical vapor deposition film form according to claim 1, wherein the sample is a semiconductor component.

3. The method for changing a physical vapor deposition film form according to claim 1, wherein the collimator has a plurality of filter components.

4. The method for changing a physical vapor deposition film form according to claim 3, wherein the plurality of filter components have the form of stripe or non-stripe.

5. The method for changing a physical vapor deposition film form according to claim 1, wherein the range of adjustment for changing the angle of the collimator relative to a vertical plan is between about −20° to 20°.

6. The method for changing a physical vapor deposition film form according to claim 1, wherein the film is composed of a material selected from the group containing the followings: Al, Mo, Nd, AlNd alloy, W, Cr, Ta, Ti, Cu, AlₓN_{y}, MoₓN_{y}, TaN, TiN, and other metal nitrides, alloys as well as combinations thereof.

7. The method for changing a physical vapor deposition film form according to claim 1, wherein the active area is a contact hole or a via pattern which lands on a non-flat area.

8. A method for changing a physical vapor deposition film form, comprising the following steps: providing at least one sample having an active area;
transferring the sample to a Physical Vapor Deposition (PVD) tool, wherein the PVD tool is installed with a collimator having an adjustable angle;
changing the angle of the collimator in the PVD tool by means of electrical drive; and
performing PVD film operations to form a protection layer having uniform thickness, the formed protection layer covering the sidewalls of the active area of the sample.

9. The method for changing a physical vapor deposition film form according to claim 8, wherein the sample is a semiconductor component.

10. The method for changing a physical vapor deposition film form according to claim 8, wherein the collimator has a plurality of filter components.

11. The method for changing a physical vapor deposition film form according to claim 10, wherein the plurality of filter components are in a form of stripe or non-stripe.

12. The method for changing a physical vapor deposition film form according to claim 8, wherein the range of adjustment for changing the angle of the collimator relative to a vertical plan is between about −20° to 20°.

13. The method for changing a physical vapor deposition film form according to claim 8, wherein the protection layer is composed of a material selected from the group containing the followings: Al, Mo, Nd, AiNd alloy, W, Cr, Ta, Ti, Cu, AlₓN_{y}, MoₓN_{y}, TaN, TiN, and other metal nitrides, alloys as well as combinations thereof.

14. The method for changing a physical vapor deposition film form according to claim 8, wherein the active area is a contact hole or a via pattern or a single side of a line pattern needed special protection.

15. A method for changing a physical vapor deposition film form, comprising the following steps:
providing at least one sample having an active area;
transferring the sample to a Physical Vapor Deposition (PVD) tool, wherein the PVD tool is installed with a collimator having an adjustable angle;
changing the angle of the collimator in the PVD tool by means of electrical drive; and
performing PVD film operations to form a barrier layer having uniform thickness, the formed barrier layer covering the sidewalls of the active area of the sample.

16. The method for changing a physical vapor deposition film form according to claim 15, wherein the sample is a semiconductor component.

17. The method for changing a physical vapor deposition film form according to claim 15, wherein the collimator has a plurality of filter components which are in a form of stripe or non-stripe.

18. The method for changing a physical vapor deposition film form according to claim 15, wherein the range of adjustment for changing the angle of the collimator relative to a vertical plan is between about −20° to 20°.

19. The method for changing a physical vapor deposition film form according to claim 15, wherein the barrier layer is composed of a material selected from the group containing the followings: Al, Mo, Nd, AiNd alloy, W, Cr, Ta, Ti, Cu, AlₓN_{y}, MoₓN_{y}, TaN, TiN, and other metal nitrides, alloys as well as combinations thereof.

20. The method for changing a physical vapor deposition film form according to claim 15, wherein the active area is a contact hole or a via pattern or a single side of a line pattern needed special barrier layer covering.
